(19) United States
(12) Patent Application Publication
(10) Pub. No.: US 2026/0026075 A1
(43) Pub. Date: Jan. 22, 2026

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Yu-Chang Lin, Hsinchu (TW); Meng-Han Lin, Hsinchu City (TW)

(73) Assignee: Powerchip Semiconductor Manufacturing Corporation, Hsinchu (TW)

(21) Appl. No.: 18/795,215

(22) Filed: Aug. 6, 2024

(30) Foreign Application Priority Data
Jul. 16, 2024 (TW) 113126627

(51) Int. Cl. H01L 29/423; H01L 23/522; H01L 23/528; H01L 27/088

(52) U.S. Cl. CPC H10D 64/518; H01L 23/5226; H10D 84/83; H01L 23/5283

(57) ABSTRACT

A semiconductor structure including a substrate, a first transistor, and a first metal gate is provided. The substrate has a front side and a back side opposite to each other. The first transistor is located on the front side. The first transistor includes a first channel region. The first metal gate is located on the back side and aligned with the first channel region.

### CROSS-REFERENCE TO RELATED APPLICATION

This application claims the priority benefit of Taiwan application serial no. 113126627, filed on Jul. 16, 2024. The entirety of the above-mentioned patent application is hereby incorporated by reference herein and made a part of this specification.

### BACKGROUND

### Technical Field

The disclosure relates to a semiconductor structure and a manufacturing method thereof, and in particular relates to a semiconductor structure having a metal gate on a back side of a substrate and a manufacturing method thereof.

### Description of Related Art

Currently, transistors with different threshold voltages are formed by adjusting the doping concentration of the pocket doped region. However, in order to form pocket doped regions with different doping concentrations, the number of photomasks must be increased. Therefore, how to effectively reduce the number of photomasks required for the manufacturing process has become the goal of continuous efforts.

### SUMMARY

A semiconductor structure and a manufacturing method thereof, which may effectively reduce the number of photomasks required for the manufacturing process of the semiconductor structure, are provided in the disclosure.

A semiconductor structure, including a substrate, a first transistor, and a first metal gate, is provided in the disclosure. The substrate has a front side and a back side that are opposite to each other. The first transistor is located on the front side. The first transistor includes a first channel region. The first metal gate is located on the back side and aligned with the first channel region.

According to an embodiment of the disclosure, in the semiconductor structure, the substrate may include a first region and a second region. The first transistor and the first metal gate are located in the first region. The semiconductor structure may further include a second transistor. The second transistor is located in the second region. The second transistor is located on the front side. The second transistor may include a second channel region. No metal gate is aligned with the second channel region on the back side.

According to an embodiment of the disclosure, in the semiconductor structure, the first transistor and the second transistor may have the same structure.

According to an embodiment of the disclosure, in the semiconductor structure, the first transistor may further include multiple first pocket doped regions. The second transistor may further include multiple second pocket doped regions. A doping concentration of the first pocket doped regions and a doping concentration of the second pocket doped regions may be the same.

According to an embodiment of the disclosure, in the semiconductor structure, the first transistor may further include multiple first source/drain regions. The second transistor may further include multiple second source/drain regions. A doping concentration of the first source/drain regions and a doping concentration of the second source/drain regions may be the same.

According to an embodiment of the disclosure, in the semiconductor structure, the substrate may include a first region and a second region. The first transistor and the first metal gate are located in the first region. The semiconductor structure may further include a second transistor and a second metal gate. The second transistor is located in the second region. The second transistor is located on the front side. The second transistor may include a second channel region. The second metal gate is located in the second region. The second metal gate is located on the back side and aligned with the second channel region.

According to an embodiment of the disclosure, in the semiconductor structure, a distance between the first metal gate and the front side may be equal to a distance between the second metal gate and the front side.

According to an embodiment of the disclosure, in the semiconductor structure, a thickness of the first metal gate may be equal to a thickness of the second metal gate.

According to an embodiment of the disclosure, in the semiconductor structure, a distance between the first metal gate and the front side may be greater than a distance between the second metal gate and the front side.

According to an embodiment of the disclosure, in the semiconductor structure, a thickness of the first metal gate may be less than a thickness of the second metal gate.

According to an embodiment of the disclosure, in the semiconductor structure, the first transistor and the second transistor may have a same structure.

According to an embodiment of the disclosure, in the semiconductor structure, the first transistor may further include multiple first pocket doped regions. The second transistor may further include multiple second pocket doped regions. A doping concentration of the first pocket doped regions and a doping concentration of the second pocket doped regions may be the same.

According to an embodiment of the disclosure, in the semiconductor structure, the first transistor may further include multiple first source/drain regions. The second transistor may further include multiple second source/drain regions. A doping concentration of the first source/drain regions and a doping concentration of the second source/drain regions may be the same.

According to an embodiment of the disclosure, the semiconductor structure may further include a first dielectric layer, a second dielectric layer, a via, and a conductive layer. The first dielectric layer is located on the back side. The second dielectric layer is located on the first dielectric layer. The first metal gate is located in the second dielectric layer. The via is located in the substrate and passes through the substrate. The conductive layer is located on the back side. The conductive layer is located in the first dielectric layer and the second dielectric layer. The conductive layer may be electrically connected to the via.

A manufacturing method of a semiconductor structure is provided in the disclosure, in which the manufacturing method includes the following operation. A substrate is provided. The substrate has a front side and a back side that are opposite to each other. A first transistor is formed on the front side. The first transistor includes a first channel region. A first metal gate is formed on the back side. The first metal gate is aligned with the first channel region.

According to an embodiment of the disclosure, in the manufacturing method of the semiconductor structure, a forming method of the first metal gate may include the following operation. A first dielectric layer is formed on the back side. A second dielectric layer is formed on the first dielectric layer. A first metal gate is formed in the second dielectric layer.

According to an embodiment of the disclosure, in the manufacturing method of the semiconductor structure, the substrate may include a first region and a second region. The first transistor and the first metal gate are located in the first region. The manufacturing method of the semiconductor structure may further include the following operation. A second transistor is formed in the second region. The second transistor is located on the front side. The second transistor includes a second channel region. A second metal gate is formed in the second region. The second metal gate is located on the back side and aligned with the second channel region.

According to an embodiment of the disclosure, in the manufacturing method of the semiconductor structure, a forming method of the second metal gate may include the following operation. The second metal gate is formed in the second dielectric layer. A distance between the first metal gate and the front side may be equal to a distance between the second metal gate and the front side.

According to an embodiment of the disclosure, in the manufacturing method of the semiconductor structure, a forming method of the second metal gate may include the following operation. A portion of the substrate is removed to form a recess in the substrate before forming the first dielectric layer. A second metal gate is formed in the second dielectric layer. The second metal gate may be located directly above the recess. A distance between the first metal gate and the front side may be greater than a distance between the second metal gate and the front side.

According to an embodiment of the disclosure, the manufacturing method of the semiconductor structure may further include the following operation. A via is formed in the substrate. The via may pass through the substrate. A conductive layer is formed on the back side. The conductive layer may be electrically connected to the via.

Based on the above, in the semiconductor structure and the manufacturing method thereof provided by the disclosure, the first transistor is located on the front side, and the first metal gate is located on the back side. The first metal gate is aligned with the first channel region of the first transistor. Therefore, the threshold voltage of the first transistor may be adjusted by applying a voltage to the first metal gate. In this way, it facilitates forming transistors with different threshold voltages in different regions on the substrate, and may effectively reduce the number of photomasks required for the manufacturing process of semiconductor structures.

In order to make the above-mentioned features and advantages of the disclosure comprehensible, embodiments accompanied with drawings are described in detail below.

### BRIEF DESCRIPTION OF THE DRAWINGS

FIG. 1A to FIG. 1F are cross-sectional diagrams of a manufacturing process of a semiconductor structure according to some embodiments of the disclosure.

FIG. 2A to FIG. 2C are cross-sectional diagrams of a manufacturing process of a semiconductor structure according to some embodiments of the disclosure.

### DETAILED DESCRIPTION OF DISCLOSED EMBODIMENTS

The following examples are described in detail with the accompanying drawings, but the provided examples are not intended to limit the scope of the disclosure. In order to facilitate understanding, the same components in the following description are described with the same symbols. In addition, the drawings are for illustrative purposes only and are not drawn in full scale. In fact, the dimensions of the various features may be arbitrarily increased or reduced for clarity of discussion.

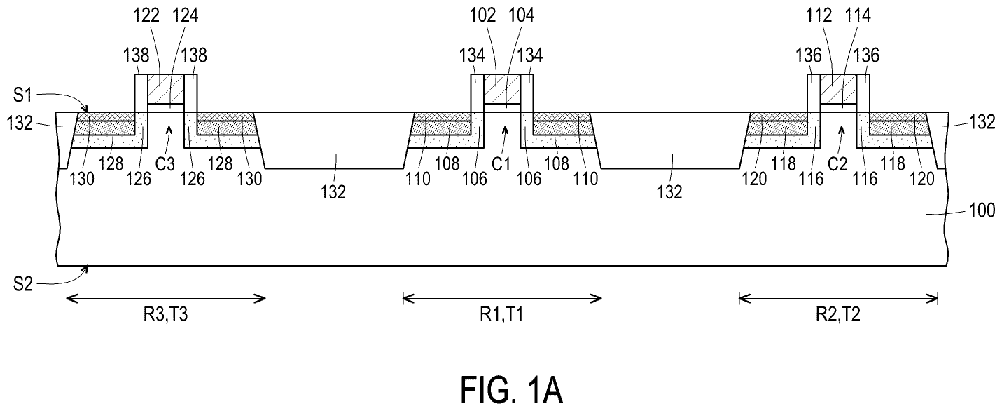

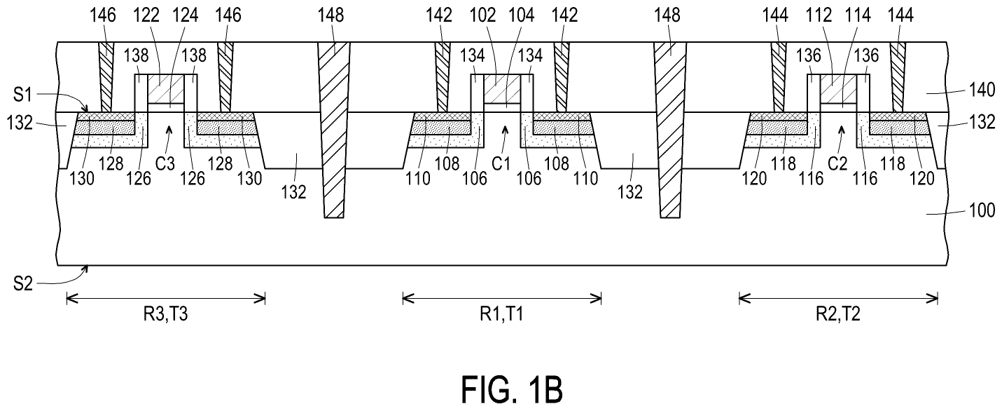

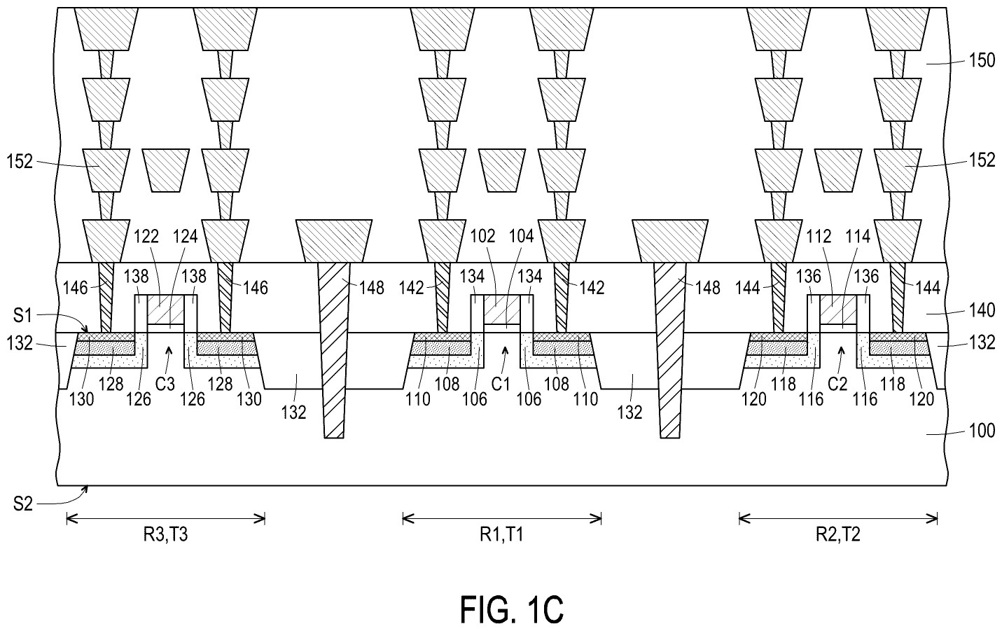

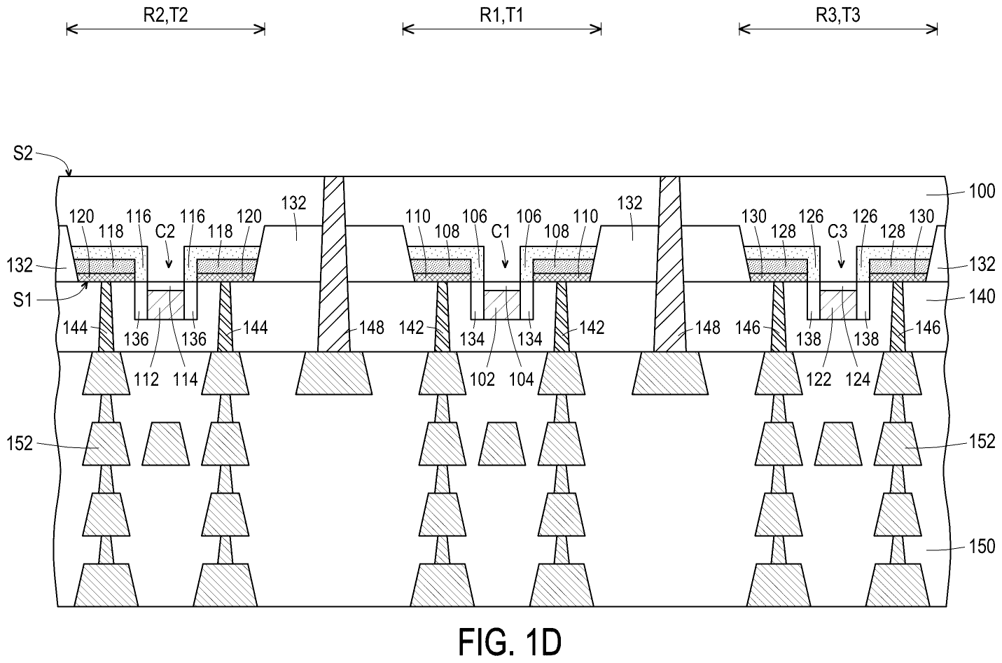

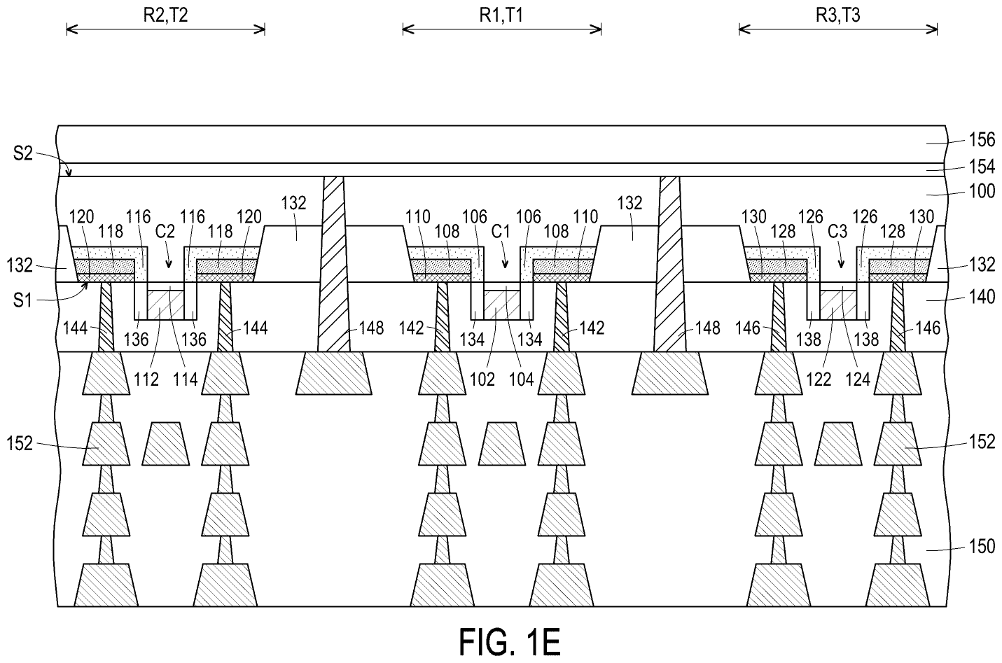

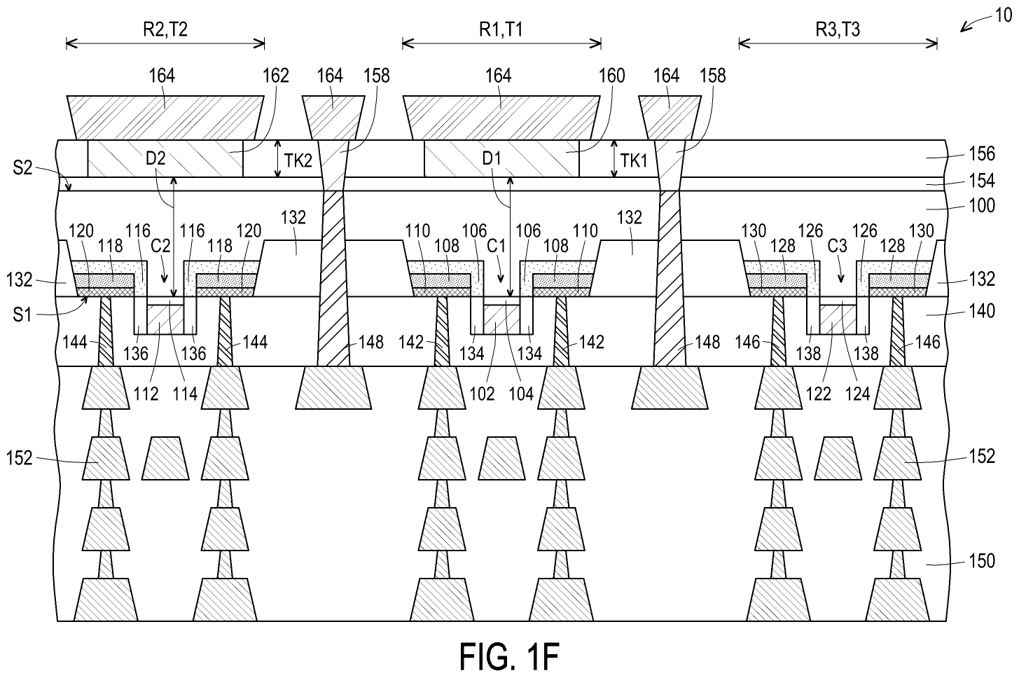

FIG. 1A to FIG. 1F are cross-sectional diagrams of a manufacturing process of a semiconductor structure according to some embodiments of the disclosure.

Referring to FIG. 1A, a substrate 100 is provided. The substrate 100 has a front side S1 and a back side S2 that are opposite to each other. In some embodiments, the substrate 100 may include a first region R1, a second region R2, and a third region R3. In some embodiments, the first region R1 may be an element region with a regular threshold voltage, the second region R2 may be an element region with a high threshold voltage, and the third region R3 may be an element region with a low threshold voltage. Furthermore, the threshold voltage of an element with a regular threshold voltage is lower than that of an element with a high threshold voltage, and the threshold voltage of an element with a regular threshold voltage is higher than that of an element with a low threshold voltage. In some embodiments, the substrate 100 may be a semiconductor substrate, such as a silicon substrate.

Next, the transistor T1 is formed on the front side S1. The transistor T1 is located in the first region R1. The transistor T1 may be a planar transistor or a fin-type transistor. In this embodiment, the transistor T1 is exemplified as a planar transistor, but the disclosure is not limited thereto. The transistor T1 includes a channel region C1. In addition, the transistor T1 may further include a gate 102, a gate dielectric layer 104, multiple pocket doped regions 106, multiple source/drain regions 108, and multiple metal silicide layers 110. The gate 102 is located on the front side S1 of the substrate 100. In some embodiments, the gate 102 may be a poly gate or a metal gate. The gate dielectric layer 104 is located between the gate electrode 102 and the substrate 100. The pocket doped regions 106 are located in the substrate 100 on two sides of the gate 102. The channel region C1 is located between the pocket doped regions 106. The source/drain regions 108 are located in the pocket doped regions 106. The metal silicide layers 110 are disposed on the source/drain regions 108.

In some embodiments, a transistor T2 may be formed in the second region R2. The transistor T2 is located on the front side S1. The transistor T2 may be a planar transistor or a fin-type transistor. In this embodiment, the transistor T2 is exemplified as a planar transistor, but the disclosure is not limited thereto. In some embodiments, the transistor T1 and the transistor T2 may have the same structure. The transistor T2 may include a channel region C2. In addition, the transistor T2 may further include a gate 112, a gate dielectric layer 114, multiple pocket doped regions 116, multiple source/drain regions 118, and multiple metal silicide layers 120. The gate 112 is located on the front side S1 of the substrate 100. In some embodiments, the gate 112 may be a poly gate or a metal gate. The gate dielectric layer 114 is located between the gate electrode 112 and the substrate 100. The pocket doped regions 116 are located in the substrate 100 on two sides of the gate 112. The channel region C2 is located between the pocket doped regions 116. In some embodiments, the doping concentration of the pocket doped region 106 and the doping concentration of the pocket doped region 116 may be the same. The source/drain regions 118 are located in the pocket doped regions 116. In some embodiments, the doping concentration of the source/drain region 108 and the doping concentration of the source/drain region 118 may be the same. The metal silicide layers 120 are disposed on the source/drain regions 118.

In some embodiments, a transistor T3 may be formed in the third region R3. The transistor T3 is located on the front side S1. The transistor T3 may be a planar transistor or a fin-type transistor. In this embodiment, the transistor T3 is exemplified as a planar transistor, but the disclosure is not limited thereto. In some embodiments, the transistor T1, the transistor T2, and the transistor T3 may have the same structure. The transistor T3 may include a channel region C3. In addition, the transistor T3 may further include a gate 122, a gate dielectric layer 124, multiple pocket doped regions 126, multiple source/drain regions 128, and multiple metal silicide layers 130. The gate 122 is located on the front side S1 of the substrate 100. In some embodiments, the gate 122 may be a poly gate or a metal gate. The gate dielectric layer 124 is located between the gate electrode 122 and the substrate 100. The pocket doped regions 126 are located in the substrate 100 on two sides of the gate 122. The channel region C3 is located between the pocket doped regions 126. In some embodiments, the doping concentration of the pocket doped region 106, the doping concentration of the pocket doped region 116, and the doping concentration of the pocket doped region 126 may be the same. The source/drain regions 128 are located in the pocket doped regions 126. In some embodiments, the doping concentration of the source/drain region 108, the doping concentration of the source/drain region 118, and the doping concentration of the source/drain region 128 may be the same. The metal silicide layers 130 are disposed on the source/drain regions 128.

In some embodiments, isolation structures 132 may be formed in substrate 100. The transistor T1, the transistor T2, and the transistor T3 may be separated from each other by the isolation structures 132. In some embodiments, the isolation structure 132 is, for example, a shallow trench isolation (STI) structure. In some embodiments, the material of the isolation structure 132 is, for example, silicon oxide.

In some embodiments, spacers 134 may be formed on the sidewalls of the gate 102, spacers 136 may be formed on the sidewalls of the gate 112, and spacers 138 may be formed on the sidewalls of the gate 122. The spacers 134, the spacers 136, and the spacers 138 may be a single-layer structure or a multi-layer structure. In some embodiments, the material of the spacers 134, the material of the 136, and the material of the 138 are, for example, silicon oxide, silicon nitride, or a combination thereof.

Referring to FIG. 1B, a dielectric layer 140 may be formed on the substrate 100. The dielectric layer 140 may be a single-layer structure or a multi-layer structure. In some embodiments, the material of the dielectric layer 140 is, for example, silicon oxide, silicon nitride, or a combination thereof.

Next, multiple contact windows 142, multiple contact windows 144, and multiple contact windows 146 may be formed in the dielectric layer 140. The contact windows 142 may be electrically connected to the source/drain regions 108. The contact windows 144 may be electrically connected to the source/drain regions 118. The contact windows 146 may be electrically connected to the source/drain regions 128. The material of the contact windows 142, the material of the contact windows 144, and the material the contact windows 146 are, for example, tungsten, titanium, titanium nitride, or a combination thereof.

Then, vias 148 may be formed in the substrate 100, the isolation structure 132, and the dielectric layer 140. The via 148 may be configured as a power via. In some embodiments, the material of the via 148 is, for example, Ti, TiN, W, Al, TaN, Cu, Co, or a combination thereof.

Referring to FIG. 1C, a dielectric layer 150 and multiple interconnect structures 152 of a back end of line (BEOL) process may be formed on the dielectric layer 140. In some embodiments, the dielectric layer 150 may be a multi-layer structure. The material of the dielectric layer 150 is, for example, silicon oxide, silicon nitride, or a combination thereof. The interconnect structures 152 are located in the dielectric layer 150. A portion of the interconnect structures 152 may be electrically connected to the contact windows 142, a portion of the interconnect structures 152 may be electrically connected to the contact windows 144, a portion of the interconnect structures 152 may be electrically connected to the contact windows 146, and a portion of the interconnect structures 152 may be electrically connected to the vias 148. The material of the interconnect structure 152 is, for example, copper, aluminum, tungsten, tantalum, tantalum nitride, titanium, titanium nitride, or a combination thereof.

Referring to FIG. 1D, a thinning process may be performed on the back side S2, thereby reducing the thickness of the substrate 100 and exposing the via 148. In this way, the via 148 may pass through the substrate 100. In some embodiments, the thinning process is, for example, a grinding process or a chemical mechanical polishing process.

Referring to FIG. 1E, a dielectric layer 154 may be formed on the back side S2. In some embodiments, the material of the dielectric layer 154 is, for example, a high dielectric constant material. In some embodiments, the dielectric layer 154 is, for example, formed by a chemical vapor deposition method.

Next, a dielectric layer 156 may be formed on the dielectric layer 154. In some embodiments, the material of the dielectric layer 156 is, for example, silicon oxide. In some embodiments, the dielectric layer 156 is, for example, formed by a chemical vapor deposition method.

Referring to FIG. 1F, conductive layers 158 may be formed in the dielectric layer 154 and the dielectric layer 156. Thereby, the conductive layer 158 may be formed on the back side S2. The conductive layer 158 may be electrically connected to the via 148. In some embodiments, the material of the conductive layer 158 is, for example, Ti, TiN, W, Al, TaN, Cu, Co, or a combination thereof. In some embodiments, the conductive layer 158 may be formed by a lithography process, an etching process, a deposition process, and a chemical mechanical polishing process.

Next, a metal gate 160 may be formed in the dielectric layer 156. Thereby, the metal gate 160 may be formed on the back side S2. The metal gate 160 may be located in the first region R1. The metal gate 160 is aligned with the channel region C1. Additionally, a metal gate 162 may be formed in dielectric layer 156. Thereby, the metal gate 162 may be formed in the second region R2. The metal gate 162 is located on the back side S2 and aligned with the channel region C2. In some embodiments, the material of the metal gate 160 and the metal gate 162 is, for example, TiN, Ti, TaN, Ta, TiAl, AlPt, Co, WN, W, Ni, Co, Ru, Mo, Au, Ag, Zn, Zr, Cr, Nb, or a combination thereof. In some embodiments, the metal gate 160 and the metal gate 162 may be formed by a lithography process, an etching process, a deposition process, and a chemical mechanical polishing process.

Then, multiple interconnect structures 164 may be formed. A portion of the interconnect structures 164 may be electrically connected to the conductive layer 158, a portion of the interconnect structures 164 may be electrically connected to the metal gate 160, and a portion of the interconnect structures 164 may be electrically connected to the metal gate 162. The material of the interconnect structure 164 is, for example, copper, aluminum, tungsten, tantalum, tantalum nitride, titanium, titanium nitride, or a combination thereof.

Hereinafter, the semiconductor structure 10 of the above embodiments will be described with reference to FIG. 1F. In addition, although the forming method of the semiconductor structure 10 is described by taking the above-mentioned method as an example, the disclosure is not limited thereto.

Referring to FIG. 1F, the semiconductor structure 10 includes a substrate 100, a transistor T1 and a metal gate 160. In some embodiments, the semiconductor structure 10 may be applied to a packaging structure of a three-dimensional integrated circuit (3D IC). The substrate 100 has a front side S1 and a back side S2 that are opposite to each other. In some embodiments, the substrate 100 may include a first region R1, a second region R2, and a third region R3. The transistor T1 is located on the front side S1. The transistor T1 includes a channel region C1. The metal gate 160 is located on the back side S2 and aligned with the channel region C1. The transistor T1 and the metal gate 160 are located in the first region.

In some embodiments, the semiconductor structure 10 may further include a transistor T2 and a metal gate 162. The transistor T2 is located in the second region R2. The transistor T2 is located on the front side S1. The transistor T2 may include a channel region C2. The metal gate 162 is located in the second region R2. The metal gate 162 is located on the back side S2 and aligned with the channel region C2. In this embodiment, the distance D1 between the metal gate 160 and the front side S1 may be equal to the distance D2 between the metal gate 162 and the front side S1. In this embodiment, the thickness TK1 of the metal gate 160 may be equal to the thickness TK2 of the metal gate 162.

In some embodiments, the semiconductor structure 10 may further include a transistor T3. The transistor T3 is located in the third region R3. The transistor T3 is located on the front side S1. The transistor T3 may include a channel region C3. In some embodiments, no metal gate is aligned with the channel region C3 on the back side S2.

In some embodiments, the bulk potential of the transistor T1 and the bulk potential of the transistor T2 may be affected by adjusting the voltage applied to the metal gate 160 and the metal gate 162. Thereby, the threshold voltage of the transistor T1 and the threshold voltage of the transistor T2 may be adjusted. In some embodiments, the transistor T1 may be a transistor element with a regular threshold voltage, and the transistor T2 may be a transistor element with a high threshold voltage. In addition, since no metal gate is aligned with the channel region C3 on the back side S2, the transistor T3 may be a transistor element with a low threshold voltage.

In some embodiments, the semiconductor structure 10 may further include a dielectric layer 154, a dielectric layer 156, vias 148, and conductive layers 158. The dielectric layer 154 is located on the back side S2. The dielectric layer 156 is located on the dielectric layer 154. The metal gate 160 is located in dielectric layer 156. The via 148 is located in the substrate 100 and passes through the substrate 100. The conductive layer 158 is located on the back side S2. The conductive layer 158 is located in the dielectric layer 154 and the dielectric layer 156. The conductive layer 158 may be electrically connected to the via 148.

In addition, for description of the remaining components of the semiconductor structure 10, reference may be made to the description of the above embodiments. In addition, the details of each component in the semiconductor structure 10 (e.g., materials and forming methods, etc.) have been described in detail in the above embodiments and are not repeated herein.

Based on the above embodiments, it may be known that in the semiconductor structure 10 and the manufacturing method thereof, the transistor T1 is located on the front side S1, and the metal gate 160 is located on the back side S2. The metal gate 160 is aligned with the channel region C1 of the transistor T1. Therefore, the threshold voltage of the transistor T1 may be adjusted by applying a voltage to the metal gate 160. In this way, it facilitates forming transistors with different threshold voltages in different regions on the substrate 100, and may effectively reduce the number of photomasks required for the manufacturing process of semiconductor structure 10.

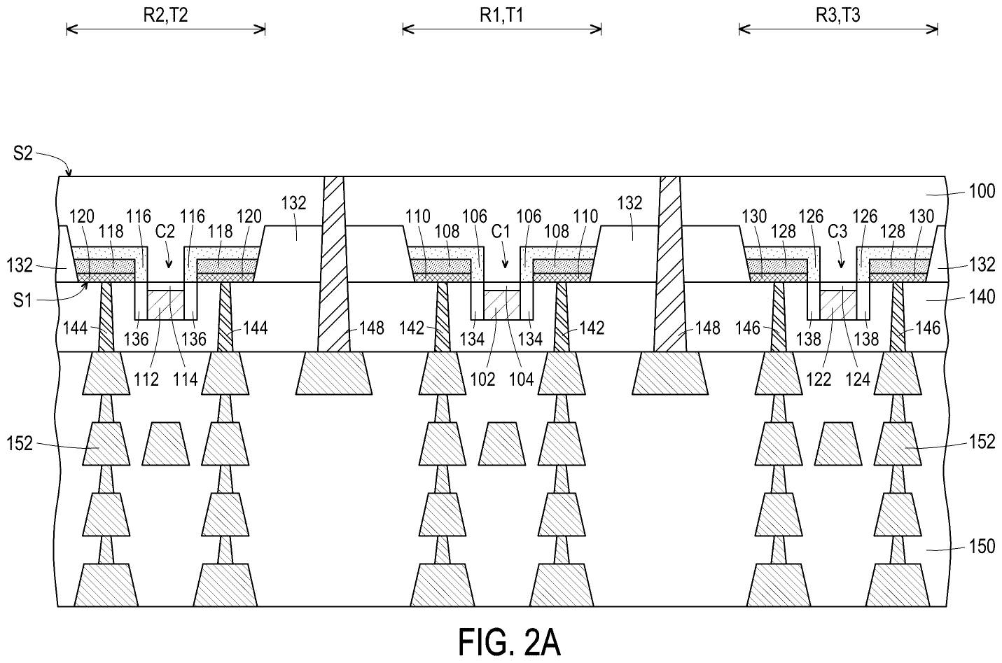

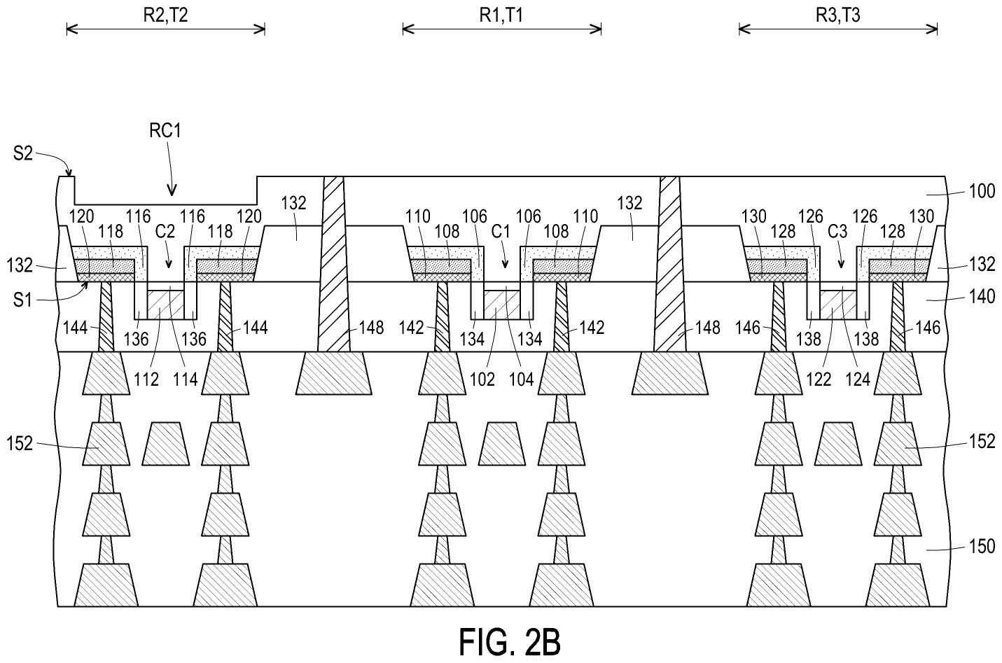

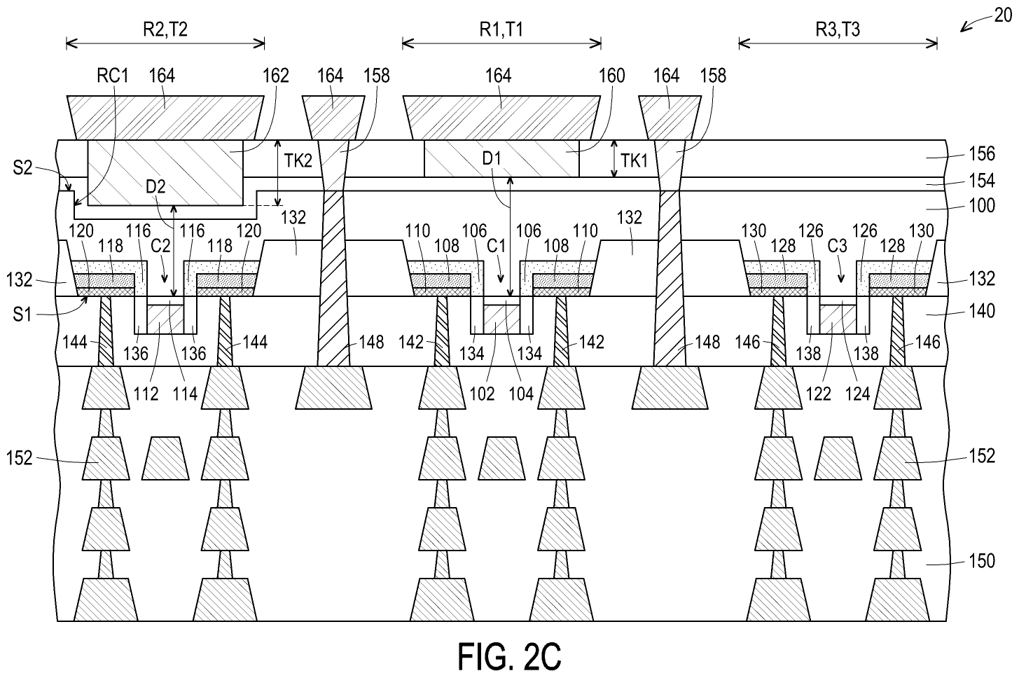

FIG. 2A to FIG. 2C are cross-sectional diagrams of a manufacturing process of a semiconductor structure according to some embodiments of the disclosure.

Referring to FIG. 2A, which may provide a structure as shown in FIG. 1D. In addition, for details of the structure of FIG. 1D, reference may be made to the description of FIG. 1A to FIG. 1E, which are not repeated herein.

Referring to FIG. 2B, a portion of the substrate 100 may be removed to form a recess RC1 in the substrate 100. In some embodiments, a portion of the substrate 100 may be removed through a lithography process and an etching process.

Referring to FIG. 2C, steps similar to those in FIG. 1E to FIG. 1F may be performed to form the semiconductor structure 20 of FIG. 2C. In addition, in the semiconductor structure 20 of FIG. 2C and the semiconductor structure 10 of FIG. 1F, the same or similar components are represented by the same symbols, and the description is omitted.

Hereinafter, the semiconductor structure 20 of the above embodiment will be described with reference to FIG. 2C. In addition, although the forming method of the semiconductor structure 20 is described by taking the above-mentioned method as an example, the disclosure is not limited thereto.

Referring to FIG. 1F and FIG. 2C, the differences between the semiconductor structure 20 of FIG. 2C and the semiconductor structure 10 of FIG. 1F are as follows. In the semiconductor structure 20, the metal gate 162 may be located directly above the recess RC1. In the semiconductor structure 20, the distance D1 between the metal gate 160 and the front side S1 may be greater than the distance D2 between the metal gate 162 and the front side S1. In the semiconductor structure 20, the thickness TK1 of the metal gate 160 may be less than the thickness TK2 of the metal gate 162.

In the semiconductor structure 20, since the distance D1 between the metal gate 160 and the front side S1 may be greater than the distance D2 between the metal gate 162 and the front side S1, even if the same voltage is applied to the metal gate 160 and the metal gate 162, the transistor T1 and the transistor T2 may have different bulk potentials. Thereby, the threshold voltage of the transistor T1 and the threshold voltage of the transistor T2 may be adjusted, and the complexity of the circuit design may be reduced. In this way, the transistor T1 may be a transistor element with a regular threshold voltage, and the transistor T2 may be a transistor element with a high threshold voltage. In addition, since no metal gate is aligned with the channel region C3 on the back side S2, the transistor T3 may be a transistor element with a low threshold voltage.

Based on the above embodiments, it may be known that in the semiconductor structure 20 and the manufacturing method thereof, the transistor T1 is located on the front side S1, and the metal gate 160 is located on the back side S2. The metal gate 160 is aligned with the channel region C1 of the transistor T1. Therefore, the threshold voltage of the transistor T1 may be adjusted by applying a voltage to the metal gate 160. In this way, it facilitates forming transistors with different threshold voltages in different regions on the substrate 100, and may effectively reduce the number of photomasks required for the manufacturing process of semiconductor structure 20.

To sum up, in the semiconductor structure and the manufacturing method thereof of the above-mentioned embodiments, the transistors are located on the front side, and the metal gates are located on the back side. The metal gates are aligned with the channel regions of the transistors. Therefore, the threshold voltage of the transistors may be adjusted by applying a voltage to the metal gates. In this way, it facilitates forming transistors with different threshold voltages in different regions on the substrate, and may effectively reduce the number of photomasks required for the manufacturing process of semiconductor structures.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A semiconductor structure, comprising:
a substrate, having a front side and a back side that are opposite to each other;
a first transistor, located on the front side and comprising a first channel region; and
a first metal gate, located on the back side and aligned with the first channel region.

2. The semiconductor structure according to claim 1, wherein
the substrate comprises a first region and a second region,
the first transistor and the first metal gate are located in the first region, and
the semiconductor structure further comprises:
a second transistor, located in the second region, located on the front side, and comprising a second channel region, wherein no metal gate is aligned with the second channel region on the back side.

3. The semiconductor structure according to claim 2, wherein the first transistor and the second transistor have a same structure.

4. The semiconductor structure according to claim 2, wherein
the first transistor further comprises a plurality of first pocket doped regions,
the second transistor further comprises a plurality of second pocket doped regions, and
a doping concentration of the first pocket doped regions and a doping concentration of the second pocket doped regions is the same.

5. The semiconductor structure according to claim 2, wherein
the first transistor further comprises a plurality of first source/drain regions,
the second transistor further comprises a plurality of second source/drain regions, and
a doping concentration of the first source/drain regions and a doping concentration of the second source/drain regions is the same.

6. The semiconductor structure according to claim 1, wherein
the substrate comprises a first region and a second region,
the first transistor and the first metal gate are located in the first region, and
the semiconductor structure further comprises:
a second transistor, located in the second region, located on the front side, and comprising a second channel region; and
a second metal gate, located in the second region, located on the back side and aligned with the second channel region.

7. The semiconductor structure according to claim 6, wherein a distance between the first metal gate and the front side is equal to a distance between the second metal gate and the front side.

8. The semiconductor structure according to claim 6, wherein a thickness of the first metal gate is equal to a thickness of the second metal gate.

9. The semiconductor structure according to claim 6, wherein a distance between the first metal gate and the front side is greater than a distance between the second metal gate and the front side.

10. The semiconductor structure according to claim 6, wherein a thickness of the first metal gate is less than a thickness of the second metal gate.

11. The semiconductor structure according to claim 6, wherein the first transistor and the second transistor have a same structure.

12. The semiconductor structure according to claim 6, wherein
the first transistor further comprises a plurality of first pocket doped regions,
the second transistor further comprises a plurality of second pocket doped regions, and
a doping concentration of the first pocket doped regions and a doping concentration of the second pocket doped regions is the same.

13. The semiconductor structure according to claim 6, wherein
the first transistor further comprises a plurality of first source/drain regions,
the second transistor further comprises a plurality of second source/drain regions, and
a doping concentration of the first source/drain regions and a doping concentration of the second source/drain regions is the same.

14. The semiconductor structure according to claim 1, further comprising:
a first dielectric layer, located on the back side; and
a second dielectric layer, located on the first dielectric layer, wherein the first metal gate is located in the second dielectric layer;
a via, located in the substrate and passes through the substrate; and
a conductive layer, located on the back side, and located in the first dielectric layer and the second dielectric layer, wherein the conductive layer is electrically connected to the via.

15. A manufacturing method of a semiconductor structure, comprising:
providing a substrate, wherein the substrate has a front side and a back side that are opposite to each other;
forming a first transistor on the front side, wherein the first transistor comprises a first channel region; and
forming a first metal gate on the back side, wherein the first metal gate is aligned with the first channel region.

16. The manufacturing method of the semiconductor structure according to claim 15, wherein forming the first metal gate further comprises:
forming a first dielectric layer on the back side;
forming a second dielectric layer on the first dielectric layer; and
forming a first metal gate in the second dielectric layer.

17. The manufacturing method of the semiconductor structure according to claim 16, wherein
the substrate comprises a first region and a second region,
the first transistor and the first metal gate are located in the first region, and
the manufacturing method of the semiconductor structure further comprises:
forming a second transistor in the second region, wherein the second transistor is located on the front side, and comprises a second channel region; and
forming a second metal gate in the second region, wherein the second metal gate is located on the back side and aligned with the second channel region.

18. The manufacturing method of the semiconductor structure according to claim 17, wherein forming the second metal gate further comprises:
forming the second metal gate in the second dielectric layer, wherein a distance between the first metal gate and the front side is equal to a distance between the second metal gate and the front side.

19. The manufacturing method of the semiconductor structure according to claim 17, wherein forming the second metal gate further comprises:
removing a portion of the substrate to form a recess in the substrate before forming the first dielectric layer;
forming a second metal gate in the second dielectric layer, wherein the second metal gate is located directly above the recess, and a distance between the first metal gate and the front side is greater than a distance between the second metal gate and the front side.

20. The manufacturing method of the semiconductor structure according to claim 15, further comprising:
forming a via in the substrate, wherein the via passes through the substrate; and
forming a conductive layer on the back side, wherein the conductive layer is electrically connected to the via.
